(19) United States
(12) Patent Application Publication
(10) Pub. No.: US 2009/0033826 A1
(43) Pub. Date: Feb. 5, 2009

(54) DISPLAY DEVICE

(75) Inventor: Takeya SHIMIZU, Kawasaki (JP)

Correspondence Address: YOUNG & THOMPSON, 209 Madison Street, Suite 500, ALEXANDRIA, VA, 22314, US

(73) Assignee: NEC LCD TECHNOLOGIES, LTD., Kawasaki (JP)

(21) Appl. No.: 12/182,495

(22) Filed: Jul. 30, 2008

(30) Foreign Application Priority Data
Jul. 31, 2007 (JP) 2007-199075

(51) Int. Cl. G02F 1/1333; H05K 5/02

(52) U.S. Cl. 349/58; 361/681

(57) ABSTRACT

A display device which enables size reduction, particularly in the frame thereof, and allows a thinner liquid crystal panel and a larger screen is provided. Positioning of a liquid crystal panel is performed by contacting the outer periphery of a back side polarizing plate, which is affixed to a second transparent substrate configuring the main part of the liquid crystal panel, with the inside of a protruded fitting portion formed on the frame of a backlight assembly. Thereby, the display panel can be positioned securely without enlarging the outside dimension of the front chassis and the frame. This enables to realize a small-size display device, particularly, size reduction in the frame of the front chassis and reduction of the outside dimension.

### CROSS-REFERENCE TO RELATED APPLICATION

This application is based upon and claims the benefit of priority from Japanese patent application No. 2007-199075, filed on Jul. 31, 2007, the disclosure of which is incorporated herein in its entirety by reference.

### BACKGROUND OF THE INVENTION

1. Field of the Invention

The present invention relates to an improvement of a display device configured such that a display panel is interposed and fixed between rectangle frame members configuring the casing.

2. Related Art

As a display device configured such that a display panel is interposed and fixed between rectangle frame members configuring the casing, a flat-panel type display device as disclosed in Japanese Patent Laid-Open Publication No. 2001-33901 (Patent Document 1) and a liquid crystal display device as disclosed in Japanese Patent Laid-Open Publication No. 2005-242047 (Patent Document 2) have been known.

FIG. 10 shows an exploded perspective view of a display device disclosed in Patent Document 1, and FIG. 11 shows a cross-sectional view taken along the line B-B′ in FIG. 10.

As shown in FIG. 10, a liquid crystal display device 100 mainly includes a front chassis 101, a liquid crystal panel 102, and a backlight assembly 103, and is configured such that the liquid crystal panel 102 is interposed and fixed between the two rectangle frame members configuring the casing, that is, the frame 104 of the backlight assembly 103 and the front chassis 101.

More specifically, the liquid crystal display device 100 is configured such that rectangle protruded fitting portions 105 are formed on the surface 107 facing the front chassis 101 of the frame 104 as shown in FIG. 10, and in a state that the liquid crystal panel 102 is positioned so as not to be movable with respect to the frame 104 bringing the outer periphery 102a of the liquid crystal panel 102 into contact with the insides 105a of the protruded fitting portions 105, the liquid crystal panel 102 is interposed and fixed between the surface 106 facing the front chassis 101 of the frame 104, in which no protruded fitting portion 105 is formed, and the surface 108 facing the frame 104 of the front chassis 101 as shown in FIG. 11.

As shown in FIG. 11, the main part of the liquid crystal panel 102 is configured of a first transparent substrate 109 and a second transparent substrate 110. Although the liquid crystal panel 102 is positioned by contacting the outer periphery 102a of the liquid crystal panel 102 to the protruded fitting portions 105 of the frame 104 as described above, as the liquid crystal panel 102 is formed such that the first transparent substrate 109 and the second transparent substrate 110 are integrally joined, if a difference is caused between the dimensions of the first transparent substrate 109 and the second transparent substrate 110, a bump may be generated on the outer periphery 102a of the liquid crystal panel 102 due to the non-uniformity of the dimensions when they are cut out. Further, a burr generated in the cutting step may remain as an acute protrusion on the cut part of the first transparent substrate 109 or the second transparent substrate 110, that is, on the outer periphery 102a of the liquid crystal panel 102.

If the bump contacts the inside 105a of the protruded fitting portion 105, the outer periphery 102a of the first transparent substrate 109 or the second transparent substrate 110 is grinded so that minute foreign materials are generated and are scattered inside the liquid crystal display device 100. Further, an acute burr formed on the outer periphery 102a of the first transparent substrate 109 or the second transparent substrate 100 may grind the inside 105a of the protruded fitting portion 105 so that minute foreign materials are generated.

Although such foreign materials are minute, once they slip into between the backlight assembly 103 and the liquid crystal panel 102, shades like black spots appear in the liquid crystal panel 102 when the liquid crystal panel 102 is illuminated from the rear side by operating the backlight assembly 103, causing a problem that the display quality of the liquid crystal panel 102 is deteriorated significantly In order to address such a problem, the invention of Patent Document 1 is configured, as shown in the cross-sectional view of FIG. 12, such that an escape slope 105b is formed inside the protruded fitting portion 105 so that a lower part of the protruded fitting portion 105 supports a position lower than the joined surfaces of the first transparent panel 109 and the second transparent panel 110, so as to prevent a bump or a burr on the outer peripheral part 102a of the liquid crystal panel 102 from contacting the inside 105a of the protruded fitting portion 105 to thereby avoid generation of foreign materials.

With this configuration, however, positioning of the liquid crystal panel 102 is still performed by using the outer periphery of the second transparent substrate 110 and the protruded fitting portion 105 on the frame 104, so that the outside dimension of the frame 104 is necessarily larger than the maximum outside dimension of the liquid crystal panel 102, which makes size reduction of the display device difficult.

Further, the first transparent substrate 109 and the second transparent substrate 110 is often made of a glass material, and as the weight and thickness has been increasingly reduced in recent years, there is a case that the thickness of the second transparent substrate 110 is 0.5 mm or smaller, so the outer periphery of the second transparent substrate 110 is extremely fragile. As such, there is a concern that a breakage or a crack may easily be caused from the outer peripheral part of the second transparent substrate 110 when vibration or impact is applied to the display device, which leads to defective display. This is an obstacle to make the liquid crystal panel 102 thinner.

Further, as positioning is performed by using the outer peripheries of the first transparent substrate 109 and the second transparent substrate 110 configuring the main part of the liquid crystal panel 102, there remains concerns in resistance to vibration and resistance to impact of the liquid crystal display device 100. Thereby, it is difficult to commonly use members in various products in which thickness of the first transparent substrate 109 and the second transparent substrate 110 differs.

On the other hand, a display device of Patent Document 2 is configured, as shown in FIG. 13, such that a back side polarizing plate 111 which is a kind of an optical film to be affixed to the back side of a second transparent substrate 110 is made to be protruded outward from the second transparent substrate 110, and positioning of the liquid crystal panel 102 is performed by putting the protruded portion of the back side polarizing plate 111 into the positioning groove 112 provided in the frame 104 of the backlight assembly 103.

With this configuration, however, positioning of the liquid crystal panel 102 is required to be performed by inserting an end part of the back side polarizing plate 111 which is larger than the second transparent substrate 110 into the inner peripheral side of the frame 104. As such, even in this case, the outside dimension of the frame 104 becomes larger than the maximum outside dimension of the liquid crystal panel 102, which makes size reduction of the display device difficult.

Further, although display devices are often used such that the screens are vertically set up, the mechanical strength of the protrusion of the back side polarizing plate 111 is weak, so even if the back side polarizing plate 111 is protruded from a longer edge side or a shorter edge side of the liquid crystal panel 102, the liquid crystal panel 102 cannot be positioned sufficiently stably if the liquid crystal panel 102 becomes larger and the weight thereof increases. As a result, such art only addresses small-type display devices and is difficult to be applied to large-type liquid crystal display devices Additionally, as the size of the back side polarizing plate 111 becomes larger exceeding the required screen size, a problem that the weight of the liquid crystal panel 102 increases beyond necessity is also involved.

### SUMMARY OF THE INVENTION

It is an exemplary object of the invention to provide a display device, capable of improving aforementioned shortcomings, enabling size deduction, in particular, enabling to reduce the size of the frame portion around the display panel, and easily allowing a liquid crystal panel to be thinner and have a larger screen.

A display device according to an exemplary aspect of the invention is configured such that a display panel formed by affixing an optical film on at least a surface of a transparent substrate configuring the main part of the display panel is inserted and fixed between a first rectangle frame member and a second rectangle frame member configuring a part of the casing.

In order to achieve the exemplary object, the display device is particularly configured such that the outside dimension of the optical film is formed to be smaller than the outside dimension of the transparent substrate, the outer periphery of the optical film is brought into contact with at least the inside of a protruded fitting portion formed on a surface, facing a second rectangle frame member, of the first rectangle frame member so that the transparent substrate is positioned with respect to at least the first rectangle frame member, and a space surrounding the outer periphery of the transparent substrate is formed around the outer periphery.

### BRIEF DESCRIPTION OF THE DRAWINGS

FIG. 1 is an exploded perspective view showing the schematic configuration of a display device according to a first exemplary embodiment of the invention;

FIG. 2 is a plan view showing the display device of the first exemplary embodiment;

FIG. 3A is a cross-sectional view taken along the line A-A′ in FIGS. 1 and 2, FIG. 3B is a cross-sectional view taken along the line B-B′ in FIGS. 1 and 2, and FIG. 3C is a cross-sectional view showing a variation of FIGS. 3A and 3B;

FIG. 4 is a plan view showing the schematic configuration of a liquid crystal panel of a display device according to a second exemplary embodiment;

FIG. 5 is a plan view showing the schematic configuration of a liquid crystal panel of a display device according to a third exemplary embodiment;

FIG. 6A is a cross-sectional view taken along the line A-A′ in FIG. 1, FIG. 6B is a cross-sectional view taken along the line B-B′ in FIG. 1, and FIG. 6C is a cross-sectional view showing a variation of FIGS. 6A and 6B, indicating the schematic configuration of a display device according to a fourth exemplary embodiment;

FIG. 7 is a cross-sectional view showing the schematic configuration of a display device according to a fifth exemplary embodiment;

FIG. 8 is a cross-sectional view showing the schematic configuration of a display device according to a sixth exemplary embodiment;

FIG. 9 is a cross-sectional view showing the schematic configuration of a display device according to a seventh exemplary embodiment;

FIG. 10 is an exploded perspective view showing an example of a generally-used display device;

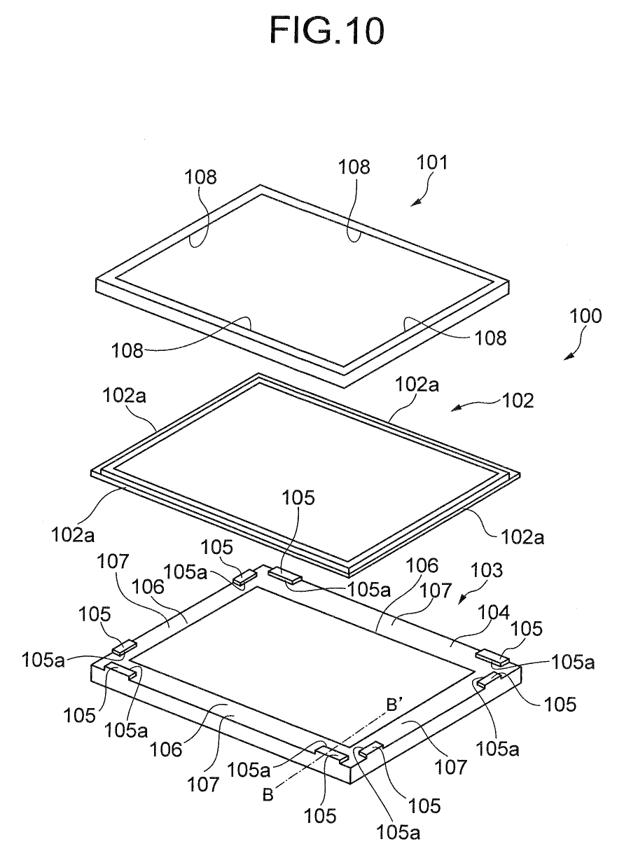

FIG. 11 is a cross-sectional view taken along the line B-B′ in FIG. 10;

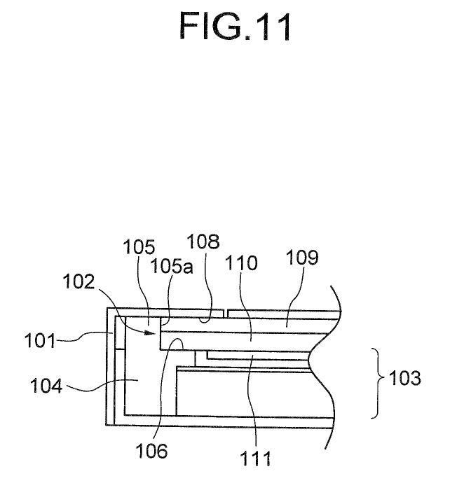

FIG. 12 is a cross-sectional view taken along the line B-B′ in FIG. 1, showing the measures to prevent generation of scrapes of a transparent substrate or a protruded fitting portion in the generally-used display device; and

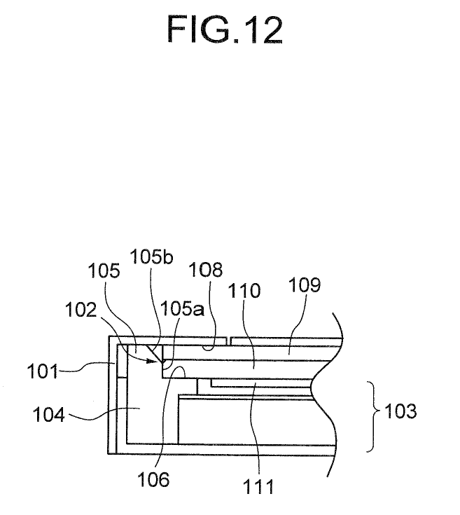

FIG. 13 is a cross-sectional view taken along the B-B′ in FIG. 10, showing another measures provided to a generally-used display device.

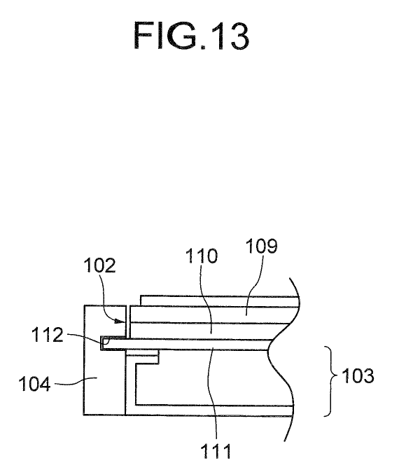

### DESCRIPTION OF EXEMPLARY EMBODIMENTS

Next, specific configurations of display devices, to which the present invention is applied, will be described by way of exemplary embodiments. Although a liquid crystal panel is used as a display panel herein, the scope of application of the present invention is riot limited to it.

### First Exemplary Embodiment

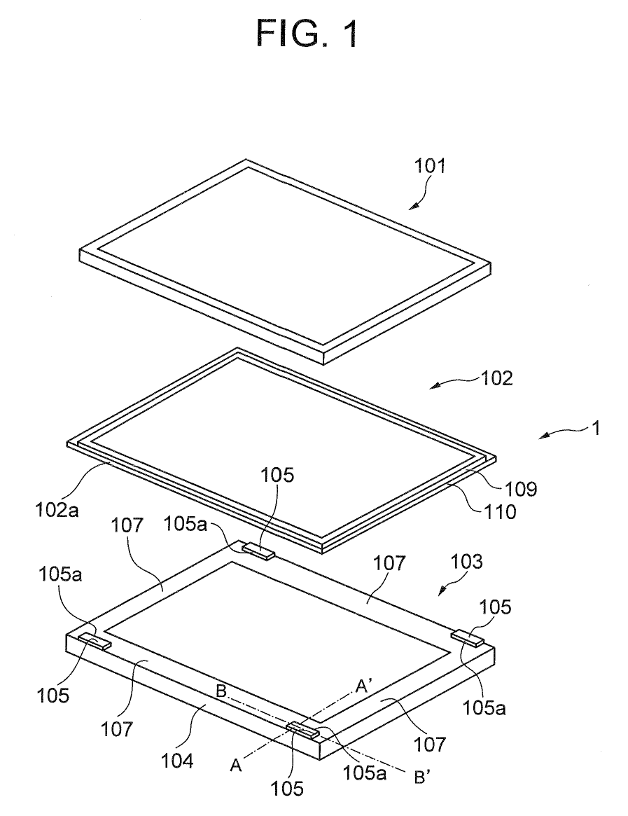

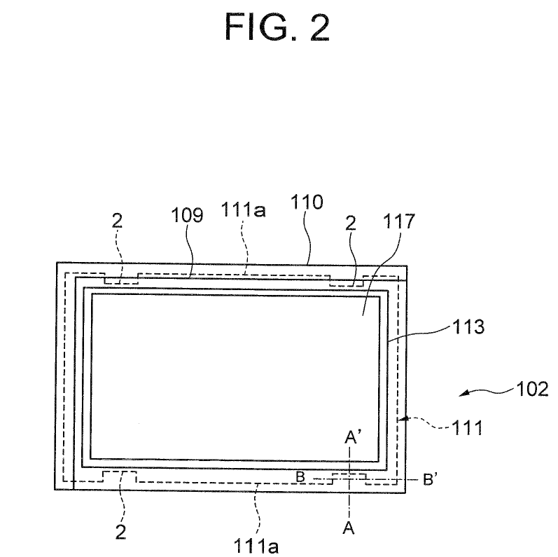

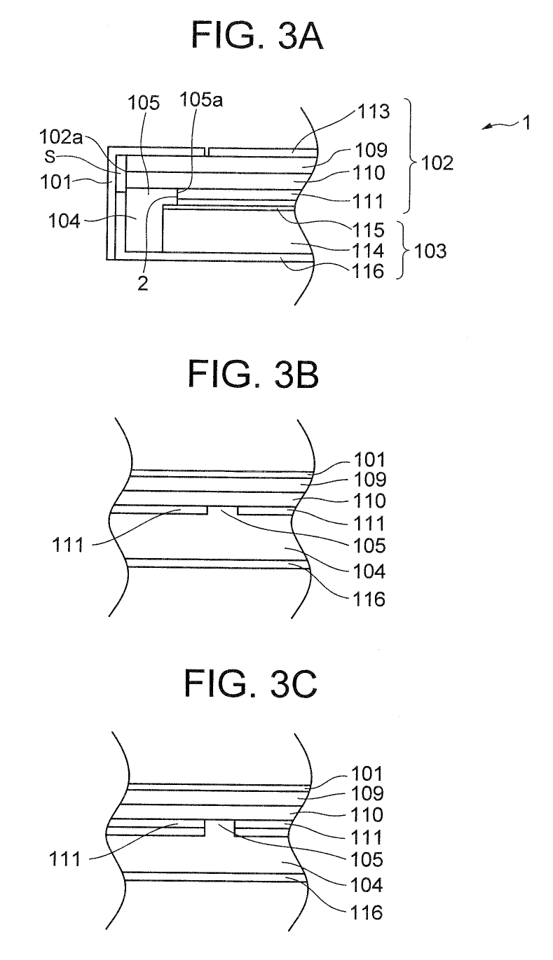

FIG. 1 is an exploded perspective view showing the schematic configuration of a display device 1 according to a first exemplary embodiment of the invention, FIG. 2 is a plan view showing the display device 1 of the first exemplary embodiment, FIG. 3A is a cross-sectional view taken along the line A-A′ in FIGS. 1 and 2, and FIG. 3B is a cross-sectional view taken along the line B-B′ in FIGS. 1 and 2. Note that hatchings in the respective cross-sectional views are omitted in order to show lead lines indicating the details.

As shown in FIG. 1, the display device 1 is configured such that a liquid crystal panel 102 is interposed and fixed between a front chassis 101 and a frame 104 of a backlight assembly 103. Each of the front chassis 101 and the frame 104 is a rectangle frame member configuring the casing.

The backlight assembly 103 includes a light guide plate 114, an optical sheet which performs light diffusion and the like, a lamp not shown, the frame 104, and a rear chassis 116. As the general structure of the backlight assembly 103 is well known, its detailed explanation is not given herein.

As shown in FIGS. 3A and 3B, the liquid crystal panel 102 is formed such that a TFT substrate on which a thin film transistor is formed, that is, a second transparent substrate 110 configuring a part of the main part of the liquid crystal panel 102, and a CF substrate on which a colored layer of RGB is disposed, that is, a first transparent substrate 109 configuring another part of the main part of the liquid crystal panel 102, are affixed to each other, and liquid crystal is injected between them. Further, a back side polarizing plate Ill which is a kind of an optical film is affixed to the back side of the second transparent substrate 110, and a front side polarizing plate 113 is affixed to the front side of the first transparent substrate 109, and then a flexible substrate such as a COF (Chip On Film) or a TCP (Tape Carrier Package), not shown, is connected to a terminal of the second transparent substrate 110. As shown in FIG. 2, the substantial display area of the liquid crystal panel 102 is an area inside the front side deflecting pate 113 and the back side polarizing plate 111, that is, a part indicated by a reference numeral 117 in FIG. 2.

As the front side polarizing plate 113 and the back side polarizing plate 111 become to have multifunctions in recent years, one formed by affixing a plurality of optical films having functions of improving brightness, improving visual angle, phase difference, and reflection prevention, in addition to a polarizing functional film, is used and has a thickness of about 0.1 to 0.5 mm in total. These functional films are comprehensively referred to as a polarizing plate herein.

As shown in FIG. 1, on the surface 107 facing the front chassis 101 of the frame 104 which is a first rectangle frame member, substantially rectangle protruded fitting portions 105 are disposed at four locations in total, on the both ends of the long edges of the both sides of the frame 104.

Further, as shown in FIG. 2, the back side polarizing plate 111 affixed to the back side of the liquid crystal panel 102, that is, to the back side of the second transparent plate 110, is formed to be smaller in vertical and horizontal outside dimensions than the second transparent substrate 110, and on the back side polarizing plate 111, positioning concavities 2, having the same shape as that of the protruded fitting portions 105, are formed at four locations of the outer periphery 111a corresponding to the protruded fitting portions 105 on the frame 104.

The liquid crystal panel 102 with the back side polarizing plate 111 affixed to the back side thereof is disposed on the frame 104 by contacting the four positioning concavities 2 of the back side polarizing plate 111 to the insides 105a of four protruded fitting portions 105 on the frame 104 internally fitted in the rear chassis 116. It is also acceptable to extend the protruded amount of the protruded fitting portions 105 so as not to contact the back side polarizing plate 111 to the frame 104 in portions other than the protruded fitting portions, as shown in FIG. 3C.

Then, the front chassis 101 is put on the rear chassis 116 of the backlight assembly 103, and by joining the front chassis 101 and the rear chassis 116, the first transparent substrate 109 and the second transparent substrate 110 are interposed between the surfaces, facing the front chassis 101, of the four protruded fitting portions 105 on the frame 104 and the surface, facing the frame 104, of the front chassis 101, whereby the liquid crystal panel 102 is securely fixed with respect to the frame 104 and the front chassis 101.

In the present exemplary embodiment, as positioning of the liquid crystal panel 102 is performed by contacting the positioning concavities 2 formed on the outer periphery of the back side polarizing plate 111 affixed to the back side of the second transparent substrate 110 with the four protruded fitting portions 105 on the frame 104, there is no need to press the outer periphery 102a of the liquid crystal panel 102 against another member for positioning. As such, a space S, surrounding the outer peripheries 102a of the first transparent substrate 109 and the second transparent substrate 110, can be formed as shown in FIG. 3, for example.

Accordingly, there is no need to take into account concerns that a bump formed when the first transparent substrate 109 or the second transparent substrate 110 are cut out is grind against another member in a state of interfering with it so that minute foreign materials are generated from the outer peripheries 102a of the first transparent substrate 109 and the second transparent substrate 110 when they are scraped, or a burr generated when the first transparent substrate 109 or the second transparent substrate 110 are cut out is grind against another member in a state of interfering with it so that minute foreign materials are generated from another member being scraped. As such, a shortcoming that shades like black spots appear on the liquid crystal panel 102 when the liquid crystal panel 102 is illuminated from the rear side by activating the backlight assembly 1.03, which deteriorates the display quality of the liquid crystal panel, can be overcome.

Further, as the liquid crystal panel 102 is positioned by contacting the positioning concavities 2 formed on the outer periphery 111a of the back side polarizing plate 111 having a relative small area affixed to the back side of the second transparent substrate 110, of the first transparent substrate 109 and the second transparent substrate 110 configuring the main part of the liquid crystal panel 102, with the inner portions 105a of the protruded fitting portions 105 on the frame 104, the liquid crystal panel 102 can be positioned securely without a large frame 104 of the backlight assembly 103. This is different from one in which positioning is performed using the outer peripheries of the first transparent substrate 109 and the second transparent substrate 110. Thereby, size reduction of the display device 1, in particular, size reduction of the frame part of the front chassis 101 and reduction of the external size can be easily realized.

Further, the positioning concavities 2 formed on the outer periphery 111a of the back side polarizing plate 111 are merely used for positioning. As the display device 1 has a configuration such that the liquid crystal panel 102 is fixed by inserting the first transparent substrate 109 and the second transparent substrate 110 which are main parts of the liquid crystal panel 102 between the two rectangle frame members configuring the casing, that is, the frame 104 of the backlight assembly 103 and the opposed surface of the front chassis 101, vibration and impact applied to the display device 1 can be addressed sufficiently.

Additionally, as the space S surrounding the outer peripheries of the first transparent substrate 109 and the second transparent substrate 110 is formed so that the outer periphery does not contact other members, even if vibration or impact is applied to the display device 1, ends of the first transparent substrate 109 and the second transparent substrate 110 will never contact other members to cause breakage or cracks Consequently, defects in display due to breakage or cracks of the first and second transparent substrates 109 and 110 can be prevented.

As a glass member used for the first and second transparent substrates 109 and 110 is made to be light and thin so that no breakage or crack is caused in the first and second transparent substrates 109 and 110 even though the outer peripheries of the first and second transparent substrates 109 and 110 are fragile, the liquid crystal panel 102 and the display device 1 can be thinner, larger, and lighter easily, and particularly, can be applied to a large-scale display device.

Further, as positioning of the liquid crystal panel 102 is performed using the back side polarizing plate 111 which is an optical file affixed to the second transparent substrate 110, irrespective of the first and second transparent substrates 109 and 110, and fixing of the liquid crystal panel 102 is performed by inserting the liquid crystal panel 102 between the frame 104 of the backlight assembly 103 and the opposed surface of the front chassis 101, there is no need to modify the backlight assembly 103 even if the thickness of the first and second transparent substrates 109 and 110 configuring the main part of the liquid crystal panel 102 is changed. It is only necessary to adjust the distance between the frame 104 of the backlight assembly 103 and the opposed surface of the front chassis 101. As such, it is possible to commonly use main members for various products in which the first and second transparent substrates 109 and 110 have different thicknesses.

Although the protruded fitting portions 105 and the positioning concavities 2 used for positioning are provided at four locations on the both ends of the both long edges of the display device 1 in FIGS. 1 and 2, they may be provided at four locations on the short edges. Although positioning is also possible by providing the protruded fitting portions 105 and the positioning concavities 2 on at least any two edges at one location each, they may be provided on three or four edges depending on the screen size and the like. Moreover, the number and the size thereof may be set arbitrarily.

As an exemplary advantage according to the invention, since the display device of the invention is configured such that the display panel is positioned by contacting the outer periphery of the optical film affixed to the transparent substrate configuring the main part of the display panel, in particular, the outer periphery of the optical film in which the outside dimension thereof is smaller than the main part of the display panel, with the inside of a protruded fitting portion formed on a rectangle frame member configuring a part of the casing, the display panel can be positioned securely without enlarging the rectangle frame member configuring the casing of the display device, including the frame of the front chassis and the backlight assembly. This enables to realize size reduction of the display device, in particular, size reduction of the frame around the display panel and the outside dimension.

Further, as another exemplary advantage according to the invention, since the display device is configured such that the front and back of the display panel is interposed and fixed between two rectangle frame members configuring a part of the casing, that is, between the frame of the backlight assembly and the opposed surface in the front chassis, vibration and impact to be applied to the display device can be addressed sufficiently

Moreover, as still another exemplary advantage according to the invention, since a space is formed to surround the outer periphery of the transparent substrate configuring the main part of the display panel so as to prevent the outer periphery of the transparent substrate from contacting other members, even if vibration and impact are applied to the display device, it is possible to prevent defectives which may be caused by a breakage or a crack in the transparent substrate.

As described above, as a glass member used as the transparent substrate becomes light and thin so that defective in display due to a breakage and a crack in the transparent substrate will not be caused even if the outer periphery of the transparent substrate is fragile, the present invention is advantageous in making a display panel and a display device thinner, larger, or lighter. Further, the present invention is also applicable to a large-scale display device.

Further, positioning of the display panel is performed by using an optical film affixed to the transparent substrate irrespective of the transparent substrate itself, and fixing of the display panel is performed by inserting the display panel between rectangle frame members configuring the casing of the display device, that is, between the frame of the backlight assembly and the opposed surface in the front chassis, for example. As such, even in the case that the thickness of the transparent substrate is changed, it is only necessary to adjust the distance between the frame of the backlight assembly and the opposed surface in the front chassis, without modifying the backlight assembly and the like. Therefore, main members can be commonly used in various products in which the thickness of transparent substrate differs.

### Second Exemplary Embodiment

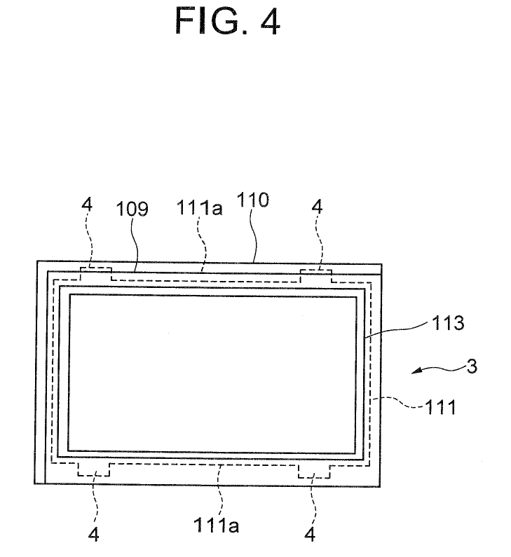

The plan view of FIG. 4 shows the schematic configuration of a liquid crystal panel 3 according to a second exemplary embodiment. The difference between the present exemplary embodiment and the one described with reference to FIGS. 1 to 3 is that positioning protrusions 4 are formed at four locations on the outer periphery 111a of the back side polarizing plate 111 affixed to the back surface of the second transparent plate 110, and the positioning protrusions 4 are brought into contact with the inside of the frame 104. Other configurations are the same as those of the exemplary embodiment described in FIG. 1.

In this case, the same effect as that of the first exemplary embodiment can be achieved with the positioning protrusions 4 formed not to protrude from the second transparent substrate 110.

### Third Exemplary Embodiment

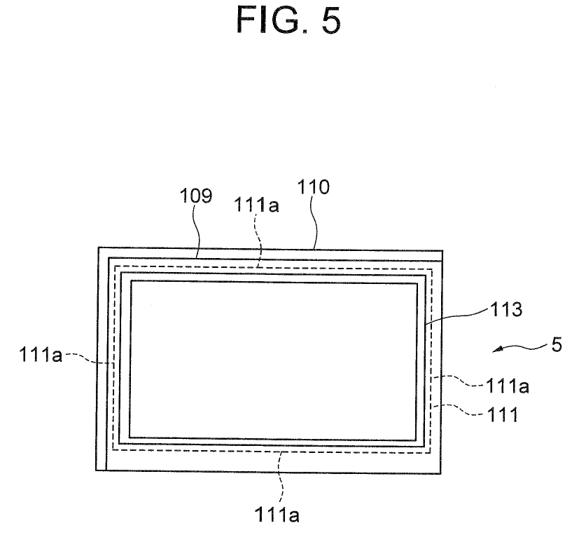

The plan view of FIG. 5 shows the schematic configuration of a liquid crystal panel 5 according to a third exemplary embodiment. The difference between the exemplary embodiment and the first and second exemplary embodiments is that no specific portion such as positioning concavities 2 and positioning protrusions 4 is provided on the outer periphery 111a of the back side polarizing plate 111, and the outer periphery 111a itself of the back side polarizing plate 111 is brought into contact with the inside of the protruded fitting part (not shown) in a rectangle circumferential wall shape formed around the frame 104 so as to surround the liquid crystal panel 102 in the surface facing the front chassis 101 in the frame 104.

In this case, the same effects as those of the first and second exemplary embodiments can be achieved by incorporating the liquid crystal panel 5 shown in FIG. 5 as it is into the protruded fitting part in a circumferential wall shape of the frame 104.

### Fourth Exemplary Embodiment

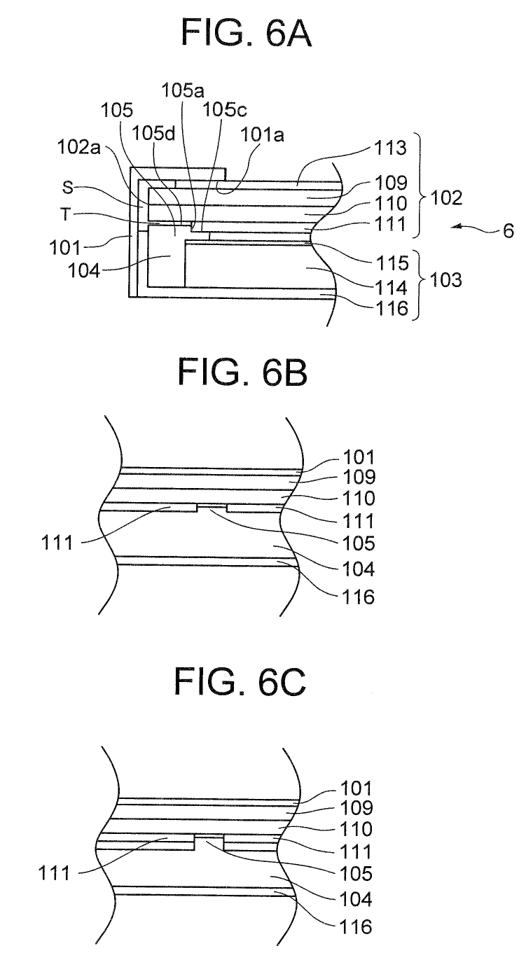

The cross-sectional views of FIGS. 6A and 6B show the schematic configuration of a display device 6 according to a fourth exemplary embodiment. FIG. 6A is a cross-sectional view taken along the line A-A′ in FIG. 1, and FIG. 6B is a cross-sectional view taken along the line B-B′.

Positioning of the liquid crystal panel 102 is performed by contacting the back side polarizing plate 111 with the insides 105a of the protruded fitting portions 105 of the frame 104, as the case of the first exemplary embodiment shown in FIG. 3. However, in order to prevent the frame 104 from contacting the back side of the second transparent substrate 110, the back surface of the back side polarizing plate 111 which is an optical film is protected overlapping by the supporting surface 105c formed of the surface facing the front chassis 101 in the frame 104 excluding the protruded fitting portions 105 so as to keep the surfaces 105d facing the front chassis 101 in the protruded fitting portions 105 distant from the back surface of the second transparent substrate 110. This is the difference from the previous exemplary embodiments. It is also acceptable to keep the back side polarizing plate 111 distant from the frame 104 in parts other than the protruded fitting portions by increasing the protruded amount of the protruded fitting portions 105, as shown in FIG. 6C.

Further, in the exemplary embodiment, the front side polarizing plate 113 affixed to the first transparent substrate 109 is extended, and the liquid crystal panel 102 is fixed such that the front and back optical films of the liquid crystal panel 102, that is, the back side polarizing plate 111 and the front side polarizing plate 113, are interposed between the supporting surface 101a formed of the surface facing the frame 104 in the front chassis 101 and the supporting surface 105c of the frame 104.

With this configuration, in addition to the space S surrounding the outer peripheries 102a of the first and second transparent substrates 109 and 110, another space T is also formed between the back side of the end of the second transparent substrate 110 and the protruded fitting portion 105 of the frame 104. As such, not only the outer peripheries 102a of the first and second transparent substrates 109 and 110 but also the back side of the end of the second transparent substrate 110 can be prevented from contacting other members.

Thereby, not only the ends of the first and second transparent substrates 109 and 110 but also the surrounding portions also have no direct contacts, and only the polarizing plates having cushioning characteristics contact the frame 104 and the front chassis 101. Consequently, the display device 6 having higher resistance to vibration and impact can be achieved.

### Fifth Exemplary Embodiment

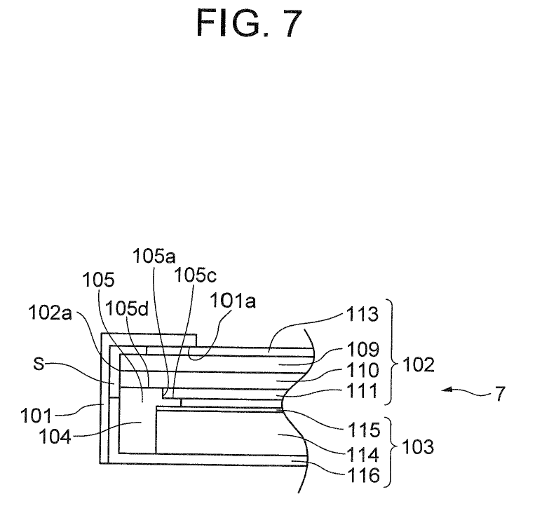

The cross-sectional view of FIG. 7 shows the schematic configuration of a display device 7 according to a fifth exemplary embodiment. This cross-sectional view is taken along the line A-A′ in FIG. 1.

Although, in the fourth exemplary embodiment, the liquid crystal panel 102 is fixed by inserting the back side polarizing plate 111 and the front side polarizing plate 113 of the liquid crystal panel 102 between the supporting surface 105c of the frame 104 and the supporting surface 101a of the front chassis 101, in the exemplary embodiment, the liquid crystal panel 102 is fixed by inserting the second transparent substrate 110 and the front side polarizing plate 113 between the supporting surface 105d formed by the surface facing the front chassis 101 in the protruded fitting portions 105 of the frame 104 and the supporting surface 101a of the front chassis 101.

In other words, the liquid crystal panel 102 is interposed and fixed between the frame 104 and the front chassis 101 in a state that the back side of the second transparent substrate 110 is supported by the supporting surface 105d which is the surfaces facing the front chassis 101 (second frame member) in the protruded fitting portions 105 provided on the frame 104 (first rectangle frame member), and the back surface of the back side polarizing plate 111 is supported by the surface facing the front chassis 101 which is a part of the frame 104 without any protruded fitting portion 105, that is, the supporting surface 105c, in this configuration.

With this configuration, although the space T between the back surface side of the end part of the second transparent substrate 110 and the protruded fitting portion 105 of the frame 104 is lost, as the supporting area increases as a whole, it is possible to reduce the weight applied to the supporting surface in unit area, and also to fix the liquid crystal panel 102 firmly.

Alternatively, it is also acceptable that the back surface of the second transparent substrate 110 is supported by the supporting surface 105d which is surfaces facing the front chassis 101 (second rectangle frame member) in the protruded fitting portions 105 whereas the surface facing the front chassis 101 in the frame 104 (first rectangle frame member) excluding the protruded fitting portions 105, that is, the part corresponding to the supporting surface 105c in FIG. 7, are made distant from the back surface of the back side polarizing plate 111 which is an optical film, and the liquid crystal panel 102 is inserted between the supporting surface 105d of the frame 104 side and the supporting surface 101a of the front chassis 101 side, that is, a configuration in which spacing is formed between the supporting surface 105c and the back side polarizing plate 111 in FIG. 7.

### Sixth Exemplary Embodiment

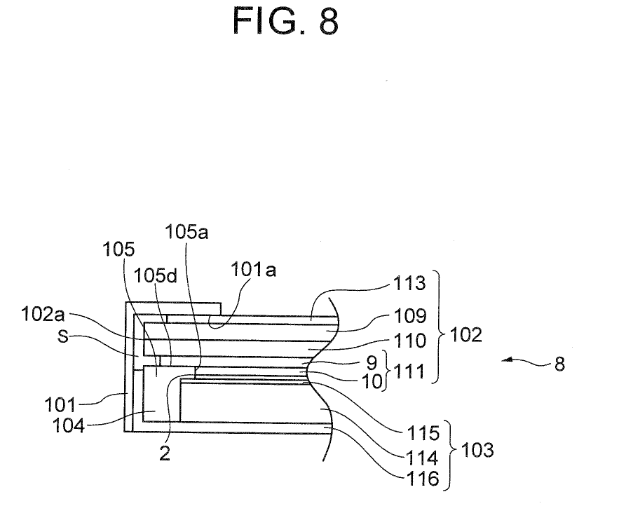

The cross-sectional view of FIG. 8 shows the schematic configuration of a display device 8 according to a sixth exemplary embodiment. This cross-sectional view is taken along the line A-A′ in FIG. 1.

As described above, a polarizing plate becomes to have multiple functions and optical films configuring the plate have a laminated structure. If any one of functions including a function of improving brightness, improving visual angle, phase difference, and preventing reflection, in addition to a polarizing function, is given to the back side polarizing plate 111, the back side polarizing plate 111 has a laminated structure in which the first and second back side optical films 9 and 10 are laminated. When the number of functions combined increases, the number of laminated layers of the optical films also increases.

In the exemplary embodiment, the positioning concavities 2 as shown in FIG. 2 are provided only to a second back side optical film 10, which is farther to the second transparent substrate 110, of the first and second back side optical films 9 and 10 configuring the back side polarizing plate 111.

More specifically, in the back side polarizing plate 111, a part overlapping the supporting surface 105d which is the surface facing the front chassis 101 (second rectangle frame member) in the protruded fitting portions 105 is configured of an optical film, that is, the first back side optical film 9, and a part not overlapping the supporting surface 105d is configured of two optical films, that is, the first and second back side optical films 9 and 10. The number of optical films of the part not overlapping the supporting surface 105d which is the surface facing the front chassis 101 in the protruded fitting portion 105 is greater by one than the number of optical film of the part overlapping the supporting surfaces 105d, and the back side polarizing plate 111 not overlapping the supporting surface 105d is thicker than the back side polarizing plate 111 of the part overlapping the supporting surface 105d.

Although it is not necessarily easy to make the part overlapping the supporting surfaces 105d thin by processing the back side polarizing plate 111 made of a signal material, the part of the back side polarizing plate 111 overlapping the supporting surface 105d can easily be made thinner by providing positioning concavities 2 to the second back side optical film 10, which is to be affixed to the outside, of the first and second back side optical films 9 and 10 configuring the back side polarizing plate 111 and affixing them to each other, as described above.

Then, the liquid crystal panel 102 is positioned by contacting the valley portions of the positioning concavities 2, which are parts of the outer periphery of the second back side optical film 10 having a larger number of layers and a greater thickness, with the insides 105a of the protruded fitting portions 105 of the frame 104, and the liquid crystal panel 102 is fixed such that the first back side optical film 9 and the front side polarizing plate 113 of the liquid crystal panel 102 are interposed between the supporting surfaces 105d formed on top of the protruded fitting portions 105 of the frame 104 and the supporting surface 101a of the front chassis 101.

With this configuration, the same actions and effects as those of the aforementioned exemplary embodiments can be achieved. Further, as the second transparent substrate 110 is protected by the first back side optical film 9 having cushioning property, the exemplary embodiment particularly exceeds the aforementioned exemplary embodiments in the property of resistance to vibration and impact.

Note that the first transparent substrate 109 may be supported by the supporting surface 101a of the front chassis 101 as the case of the exemplary embodiment shown in FIG. 3, instead of supporting the front side polarizing plate 113 by the supporting surface 101a of the front chassis 101, in FIGS. 6A to 8.

### Seventh Exemplary Embodiment

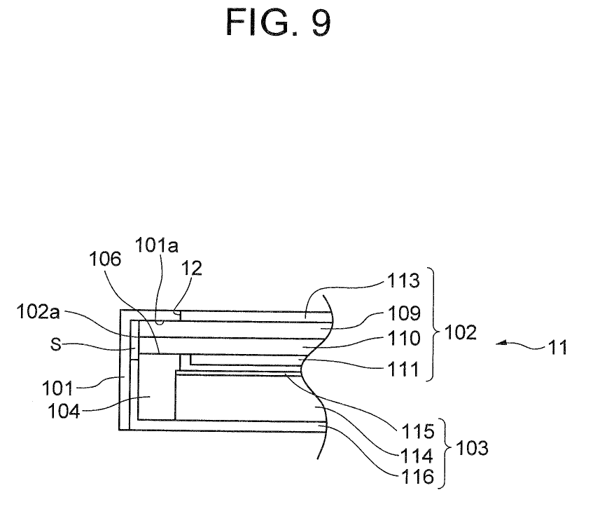

The cross-sectional view of FIG. 9 shows the schematic configuration of a display device 11 according to a seventh exemplary embodiment. This cross-sectional view is corresponding to the cross-sectional view taken along the line A-A′ in FIG. 1.

Although the first to sixth exemplary embodiments have the configuration in which the protruded fitting portions 105 are provided on the frame 104 side of the backlight assembly 103 to position the liquid crystal panel 102, the seventh exemplary embodiment adopts a configuration in which the liquid crystal panel 102 is positioned by using protruded fitting portions 12 provided on the front chassis 101 side. This is the difference from the above-described exemplary embodiments.

As shown in FIG. 9, the inner periphery of the frame part of the front chassis 101, which is a first rectangle frame member, is used as a protruded fitting portion 12 which is in a circumferential wall shape around the front chassis 101 in the seventh exemplary embodiment. The outer periphery of the front side polarizing plate 113 having a small outside dimension, affixed to the front side of the liquid crystal panel 102, that is, the front side of the first transparent substrate 109, is brought into contact with the inside of the protruded fitting portion 12 to thereby position the liquid crystal panel 102 with respect to the front chassis 101. Further, in a state that the front surface of the first transparent substrate 109 is supported by the supporting surface 101a formed on the surface facing the frame 104 (second rectangle frame member) in the front chassis 101, and the back surface of the second transparent substrate 110 is supported by the surface 106 facing the front chassis 101 in the frame 104, the liquid crystal panel 102 is interposed and fixed between the front chassis 101 and the frame 104.

Even in this case, the end parts of the first and second transparent substrates 109 and 110 do not contact other members in the whole periphery, so that the same actions and effects as those of the previous exemplary embodiments can be achieved.

Although the liquid crystal panel 102 is supported by the supporting surface 101a of the front chassis 101 and the opposed surface 106 in the frame 104, the back surface of the second transparent substrate 110 may be supported directly by the opposed surface 106, or the back side polarizing plate 111 may be extended to the top surface of the opposed surface 106 so that the back surface of the second transparent substrate 110 is supported by the opposed surface 106 via the back side polarizing plate 111.

In this exemplary embodiment, as the liquid crystal panel 102 is positioned by using the front chassis 101 which is a first rectangle frame member and the front side polarizing plate 113 affixed to the first transparent substrate 109, the frame 104 which is a second rectangle frame member merely supports the liquid crystal panel 102 and is not involved in positioning of the liquid crystal panel 102.

The seventh exemplary embodiment can be realized in combination with the first to sixth exemplary embodiments appropriately. Thus, it is also possible to form protruded fitting portions on both the first rectangle frame member and the second rectangle frame member, that is, the front chassis 101 and the frame 104, to thereby position the outer periphery of the front side polarizing plate 113 with the protruded fitting portions on the front chassis 101 side (configuration of the seventh exemplary embodiment), and also to position the outer periphery of the back side polarizing plate 111 with the protruded fitting portions on the frame 104 side (configuration of the first to sixth exemplary embodiments).

As described above, in the first to sixth exemplary embodiments described above, the outside dimension of the back side polarizing plate 111 for positioning the liquid crystal panel 102 is made smaller than the outside dimension of the second transparent substrate 110, and the outer periphery of the back side polarizing plate 111 is brought into contact with the protruded fitting portions 105 on the frame 104 which is the first rectangle frame member configuring a part of the casing, to thereby position the liquid crystal panel 102. Thereby, the space S surrounding the outer peripheries of the first and second transparent substrates 109 and 110 is formed so that the end parts of the liquid crystal panel 102 do not contact other members such as the front chassis 101 and the backlight assembly 103.

Meanwhile, in the seventh exemplary embodiment, the outside dimension of the front side polarizing plate 113 for positioning the liquid crystal panel 102 is made smaller than the outside dimension of the first transparent substrate 109, and the outer periphery of the front side polarizing plate 113 is brought into contact with the protruded fitting portion 12 formed by the inner periphery of the frame part of the front chassis 101 which is the first rectangle frame member configuring a part of the casing to thereby position the liquid crystal panel 102. Thereby, the space S surrounding the outer peripheries of the first and second transparent substrates 109 and 110 is formed so that the end parts of the liquid crystal panel 102 do not contact other members such as the front chassis 101 and the backlight assembly 103.

Accordingly, every configuration of the first to seventh exemplary embodiments is common in that the outside dimension of the polarizing plate as an optical film affixed to the surface of the side near the first rectangle frame member on which protruded fitting portions are formed, of the front and back of the liquid crystal panel 102, is smaller than the outside dimension of the transparent substrate configuring the main part of the liquid crystal panel 102, and at least a part of the outer periphery of the polarizing plate as an optical film is brought into contact with the inside of the protruded fitting portion formed on the first rectangle frame member to thereby position the liquid crystal panel 102 with reference to the first rectangle frame, whereby a space is formed around the outer periphery of the transparent substrate configuring the main part of the liquid crystal panel 102, and the liquid crystal panel 102 is interposed and fixed between the first rectangle frame member and the second frame member.

Therefore, for the second transparent substrate 110 which is a TFT substrate and the first transparent substrate 109 which is a CF substrate, there is no limitation for measures to be taken. Further, regarding the CF substrate, a structure in which no colored layer is arranged in the display area or an RGBW structure in which colored layers of RGB are arranged in the display area together with an area having no colored layer can be adopted. Further, any liquid crystal displaying systems including the TN (Twisted Nematic) system, the IPS (In-Plane Switching) system, the FFS (Fringe-Field Switching) system, and the VA (Vertical Alignment) system may be adopted, and any types of liquid crystal display devices including PDP (Plasma Display Panel) and EL (Electroluminescence Display) can be adopted.

While the invention has been particularly shown and described with reference to exemplary embodiments thereof, the invention is not limited to these embodiments. It will be understood by those of ordinary skill in the art that various changes in form and details may be made therein without departing from the spirit and scope of the present invention as defined by the claims.

What is claimed is:

1. A display device, comprising:
a display panel formed by affixing an optical film on at least one surface of a transparent substrate configuring a main part of the display panel; and
a first rectangle frame member and a second rectangle frame member configuring a part of a casing, between which the display panel is interposed and fixed, wherein
an outside dimension of the optical film is formed to be smaller than an outside dimension of the transparent substrate,
an outer periphery of the optical film is brought into contact with at least an inside of a protruded fitting portion formed on a surface, facing a second rectangle frame member, of the first rectangle frame member so that the transparent substrate is positioned with respect to at least the first rectangle frame member, and
a space surrounding an outer periphery of the transparent substrate is formed around the outer periphery of the transparent substrate.

2. The display device, according to claim 1, wherein the first rectangle frame member is configured of a frame of a backlight assembly, and the second rectangle frame member is configured of a front chassis.

3. The display device, according to claim 1, wherein the first rectangle frame member is configured of a front chassis, and the second rectangle frame member is configured of a frame of a backlight assembly.

4. The display device, according to claim 1, wherein a positioning concavity is formed in the outer periphery of the optical film which contacts the inside of the protruded fitting portion.

5. The display device, according to claim 1, wherein a positioning protrusion is formed on the outer periphery of the optical film which contacts the inside of the protruded fitting portion.

6. The display device, according to claim 1, wherein the protruded fitting portion is formed around the first rectangle frame member so as to surround the display panel.

7. The display device, according to claim 1, wherein a surface of the transparent substrate is supported by a surface, facing the second rectangle frame member, of the protruded fitting portion, and a surface of the optical film is supported by a surface, facing the second rectangle frame member, of the first rectangle frame member in which the protruded fitting portion is not formed.

8. The display device, according to claim 1, wherein a surface of the transparent substrate is supported by a surface facing the second rectangle frame member of the protruded fitting portion, and a surface facing the second rectangle frame member, except for the protruded fitting portion, of the first rectangle frame member is distant from a surface of the optical film.

9. The display device, according to claim 1, wherein a surface of the optical film is supported by a surface facing the second rectangle frame member of the first rectangle frame member except for the protruded fitting portion, and a surface facing the second rectangle frame member of the protruded fitting portion is distant from a surface of the transparent substrate.

10. The display device, according to claim 1, wherein the optical film includes a part overlapping a surface facing the second rectangle frame member of the protruded fitting portion and a part not overlapping the surface facing the second rectangle frame member,
the part not overlapping the surface facing the second rectangle frame member is formed to be thicker than the part overlapping the surface facing the second rectangle frame member, and
an outer periphery of the optical film in the thick part contacts the inside of the protruded fitting portion.

11. The display device, according to claim 1, wherein the optical film is made of a plurality of films affixed to each other.

12. The display device, according to claim 10, wherein the optical film is made of a plurality of films affixed to each other, and includes the part overlapping the surface facing the second rectangle frame member of the protruded fitting portion and the part not overlapping the surface facing the second rectangle frame member,
a number of films of the part not overlapping the surface facing the second rectangle frame member is larger than a number of films of the part overlapping the surface facing the second rectangle frame member, and
the outer periphery of the optical film in the part having a larger number of films contacts the inside of the protruded fitting portion.

13. The display device, according to claim 1, wherein the display panel is a liquid crystal panel.
